(19) United States
(12) Patent Application Publication
(10) Pub. No.: US 2011/0086525 A1
(43) Pub. Date: Apr. 14, 2011

(54) Circuit Board Arrangement and Electric Connection Module

(75) Inventors: Klaus Begemann, Schieder-Schwalenberg (DE); Ansgar Kathmann, Hoxter (DE); Markus Kettern, Lemgo (DE)

(73) Assignee: PHOENIX CONTACT GMBH & CO. KG, 32825 Blomberg (DE)

(21) Appl. No.: 12/918,532

(22) PCT Filed: Feb. 18, 2009
(86) PCT No.: PCT/EP2009/001162

§ 371 Date: Aug. 20, 2010

(30) Foreign Application Priority Data
Feb. 20, 2008 (DE) 10 2008 010 160.5

(51) Int. Cl. H01R 12/51; H05K 1/00; H05K 3/34

(52) U.S. Cl. 439/83; 29/843

(57) ABSTRACT

The invention relates to a circuit board arrangement and to an electric connection module having a carrier module and at least one electric contact, and to an attachment module, wherein the invention provides that the attachment module is used for the protection against the touch of the at least one electric contact, and is made of an elastic plastic, and wherein further the carrier module is provided for accomodating the at least one electric contact. For this purpose the carrier module is made of another temperature-resistant plastic in order to be suitable for a soldering process at high temperatures. During the soldering process, at least one electric contact can be soldered to a circuit board.

The invention relates to a circuit board arrangement having a circuit board provided with an electric connection module, and an electric connection module.

From DE 44 00 484 C3 a low voltage device has become known comprising an electrically well insulated housing that consists of an impact-resistant plastic material. Circuit boards to which screw clamps are soldered are inserted in the housing interior. The housing provides mechanical protection.

For manufacturing an electric circuit, circuit boards are typically assembled with small, electronic components and soldered in a soldering process. For establishing electric bonding, electric end connectors such as plug connectors or spring-loaded contacts or else screwed connection clamps are employed with conductors leading away from the circuit board. As a rule these connection modules are comparatively large components. These large components cannot readily be soldered at the same time as very small components such that one joint soldering process is often impossible.

Another problem in the known prior art is that in present-day reflow soldering processes only high-temperature resistant plastic materials can be employed.

DE 10 2006 026 753 B3 has disclosed a battery contact module configured as an SMD component for a hearing aid, provided with a plastic frame consisting of a liquid crystal polymer (LCP). This allows the plastic frame with the circuit board 11 to be exposed to a reflow oven temperature of 260° C. for two to three seconds. The intended application does not require any particular mechanical and electrically insulating specifications for the plastic.

The drawback of this temperature-resistant plastic is, however, that the physical requirements regarding the tensile yield strength or the elasticity of a mechanical latch connection may not be met in full.

Another drawback is that many of these high-temperature resistant plastics do not sufficiently ensure all of the electric properties in view of the required insulation.

This is why mechanically flexible plastics are used although they are not so high-temperature resistant so as to often render it impossible to solder the connection modules to a circuit board concurrently with the other electric and electronic components in one common reflow soldering process. Additional manual soldering or additional soldering processes for the connection modules will become necessary causing considerably increased process steps and thus higher costs.

Against the background of the indicated prior art it is therefore the object of the present invention to reduce the manufacturing steps for circuit boards provided with electronic components and a connection module so as to reduce costs.

It is another aspect of the object of preferred specific embodiments of the invention to provide an electric connection module and a circuit board arrangement with which to allow one common soldering process together with the other components to be arranged on a circuit board.

This object is solved by an electric connection module having the features of claim 1 and by a circuit board arrangement having the features of claim 7.

Preferred specific embodiments of the invention are the subjects of the corresponding subclaims. Further preferred features of the invention are indicated in the exemplary embodiment.

The electric connection module according to the invention comprises at least one carrier module, at least one electric contact, and at least one attachment module. It is provided for the carrier module to serve to accommodate the at least one electric contact and to consist of a flexible plastic. Furthermore the attachment module is provided as a contacting protection for the electric contact. The carrier module consists of a different temperature-resistant plastic so as to be suitable for high-temperature soldering processes. In the soldering process at least one or the electric contact can be soldered to the or a circuit board.

The invention has many advantages. One considerable advantage is the dual electric connection module consisting of a carrier module and an attachment module. According to the invention the carrier module may be provided of a temperature-resistant plastic for carrying out one common soldering process together with the other electric and electronic components on a circuit board. This allows considerable saving of work since no additional, separate manual or automatic soldering process is required.

According to the invention the electric contacts for bonding can be inserted mechanically or manually or in another way into the carrier module during manufacturing where they are retained separate from one another and pre-positioned relative to one another. Then the carrier module can in particular be brought to a circuit board and positioned mechanically. This only requires a conventional picker arm to position in this way one, two, or e.g. ten or twenty or more contacts on the circuit board in defined locations. This considerably reduces the process steps required for positioning the contacts.

The carrier module consisting of a temperature-resistant plastic is also suitable for high-temperature soldering processes such as the reflow process. Separate soldering of the connection module is dispensed with.

The attachment module consists of a flexible plastic. An attachment module of a flexible plastic offers significant advantages since the mechanical properties of flexible plastic are better over the standard high-temperature resistant plastic of which the carrier module is made. As a rule, high-temperature resistant plastic is more brittle, having less elongation at break. An attachment module of a flexible plastic for contacting protection and for mechanical protection of the contacts thus offers considerable advantages.

The combination of a high-temperature resistant plastic for the carrier module and a flexible plastic for the attachment module allows for a simplified and cost-effective manufacturing while the mechanical properties such as mechanical strength of the electric connection module remain high-level or can even be improved.

Preferably an electric contact that can be soldered to the circuit board may be that of an electric/electronic component.

In an advantageous configuration the attachment module can be attached to the carrier module such that following the soldering process the attachment module is placed, in particular clicked, onto the carrier module.

Or else it is conceivable to pre-assemble an electric connection module by way of inserting the electric contacts into the carrier module and closing the carrier module by the attachment module to allow anti-loss protection of the accommodated electric contacts even when they are not soldered.

Before soldering for example the attachment module can be removed for the soldering process since as a rule the attachment module does not consist of such a high-temperature resistant plastic and might be damaged during soldering for one, and for another might unduly prolong the soldering process since present-day soldering processes tend to provide for the entire circuit board to be heated for soldering.

An attachment module in place during soldering would increase the heat capacity already due to its mass, thus causing the soldering process to be prolonged. Moreover the attachment module might have a heat-insulating effect, acting as a heat shield which would again cause a prolonged soldering process.

In preferred embodiments the attachment module serves as a mechanical connection and a mechanical protection of the contacts it contains.

Advantageously the temperature-resistant plastic of the carrier module is suitable for high-temperature soldering processes. Particular soldering processes may for example provide standard temperatures of approximately 240 to 260° C.

Preferably the temperature-resistant plastic is also suitable for temperatures of approximately 280° C. The specification “approximately 280° C.” is not to be understood as a precise limit but the temperature-resistant plastic may as well be suitable for soldering processes at 290° C. or 300° C. or still higher temperatures. Depending on the soldering process employed temperature-resistant plastics may be employed withstanding for example only temperatures of 250° C. or 260° C. in particular temporarily or for a longer time to ensure perfect soldering with these temperatures. The exact temperatures depend on the soldering process and its conditions (temperatures and application times).

In a preferred more specific embodiment of the invention at least part of the carrier module consists of a liquid crystal polymer.

On the whole the electric connection module according to the invention and its specific embodiments are an advantageous further development in which the requirements for the soldering process are separated from the mechanical requirements for the components. While the carrier module consists of temperature-resistant plastic and pre-positions the electric contacts for the soldering process, the attachment module ensures the required mechanical properties, guaranteeing the required electric properties in terms of the insulating effect and contacting protection.

The circuit board arrangement according to the invention comprises at least one circuit board and at least one electric connection module provided thereon, the electric connection module comprising at least one carrier module to receive at least one electric contact for soldering to be soldered to the circuit board in a soldering process, and at least one attachment module. The attachment module is provided as a contacting protection of the at least one electric contact and consists of a flexible plastic. Furthermore the carrier module consists of a different temperature-resistant plastic so as to be suitable for high-temperature soldering processes.

The circuit board arrangement according to the invention also has considerable advantages. The carrier module and the circuit board can be processed in one common soldering process such that separate soldering to finish the electric connection module is dispensed with. Moreover, components can be mounted concurrently with assembling the remaining circuit board so as to save considerable work.

In preferred specific embodiments the circuit board of the circuit board arrangement according to the invention comprises at least one electric or electronic component for soldering which is soldered concurrently with the common soldering process of the at least one electric contact.

Even considerable differences in the sizes of the connection module and the electronic or electric components for soldering do not generate any basic difficulties in the common soldering process. Since the covering module of the connection module is preferably not attached before soldering is finished, the heat capacities of the components do not differ much, allowing common soldering.

To obtain similar heat capacities, the carrier module of the electric connection module is preferably lightweight, consisting for example only of a skeleton frame or having openings and bores to keep the weight down while guaranteeing the pre-positioning of the electric contacts at the carrier module. These measures guarantee a reliable soldering process even for large-dimension contacts.

The attachment module consists of a flexible plastic that may not be as temperature-resistant as is the plastic of the carrier module. A high-temperature resistant plastic is as a rule not required for the attachment module since the attachment module is typically only attached after the soldering process.

With the circuit board arrangement according to the invention it is conceivable and preferred for the attachment module to be fastened to the carrier module, for example snapped on to prevent its coming off unaided.

It is also conceivable and preferred to fasten the attachment module immediately to the circuit board to mechanically protect the contacts and to ensure contacting protection.

In preferred specific embodiments the attachment module is fastened to a receiving module which preferably also receives at least part of the circuit board. Then in particular at least part of the circuit board is enclosed in the attachment module and the receiving module. The circuit board may for example be arranged on another component or a fastening device through the receiving module.

Preferred specific embodiments of the invention are the subjects of the corresponding subclaims. Further preferred features of the invention are indicated in the exemplary embodiment.

Other than the configurations of the invention described above, further advantageous configurations of the invention are indicated in the dependent claims.

An embodiment of the invention is illustrated in the drawings purely schematically and will be described in more detail below.

The figures show in:

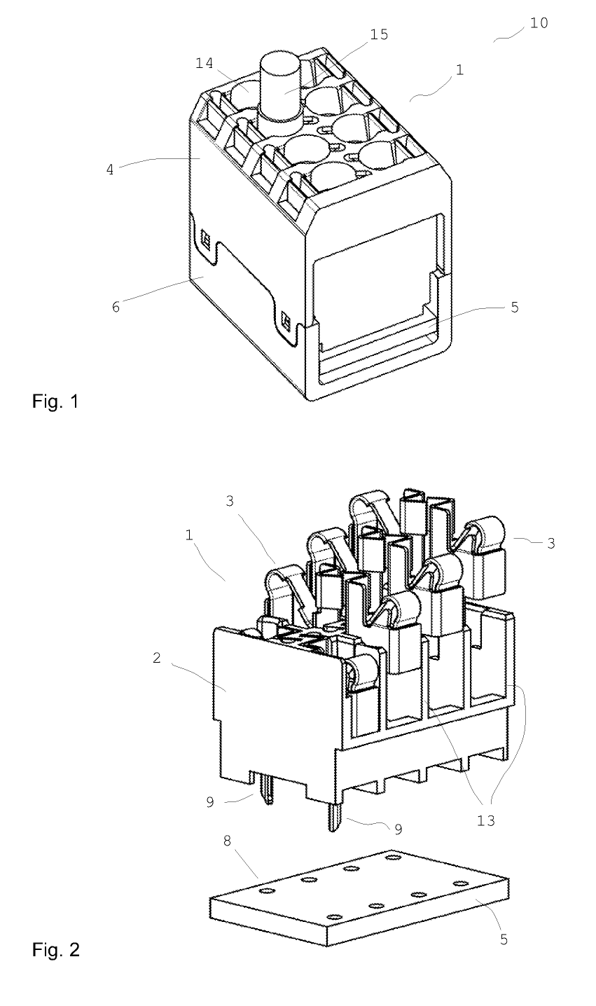

FIG. 1 a perspective overall view of a circuit board arrangement according to the invention

FIG. 2 a perspective view of the circuit board and the carrier module; and

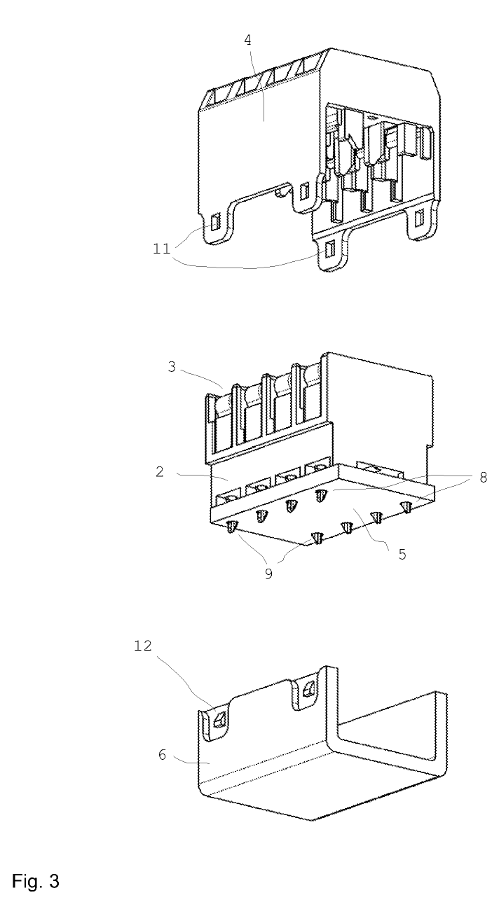

FIG. 3 an exploded view of the circuit board arrangement according to FIG. 1.

FIG. 1 illustrates a perspective overall view of a circuit board arrangement 10 according to the invention, presently comprising a circuit board 5 and an electric connection module 1. More electric components may be provided at the circuit board arrangement 10.

The circuit board 5 is bonded via the electric connection modules 1. To this end, terminal openings 14 are provided in the attachment modules 4 for the conductors 15 to be inserted to thus connect these with the circuit board 5 via the contacts 3.

In the present exemplary embodiment the attachment modules 4 of the two electric connection modules 1 are snapped into one common receiving module 6 which receives and secures the circuit board 5. Generally it is possible for further electric or electronic components to be arranged on the circuit board 5.

FIG. 2 is a slightly perspective illustration of the circuit board 5 and the carrier module 2 of the electric connection module 1. For clarification the circuit board and the carrier module are illustrated spaced apart from one another to show the two components in relation to one another.

The carrier module 2 comprises partitions 13 separating the compartments of the carrier module from one another and allowing precise positioning relative to one another of the contacts 3 received in each compartment.

As becomes clear from FIG. 2, this allows automatic assembling of the circuit board 5 with the carrier module 2. A carrier module 2 may comprise one, two, or more contacts 3 which are concurrently bonded with the circuit board 5 in mounting. This considerably facilitates in particular automatic assembling of circuit boards since, as is presently illustrated, eight contacts 3 are concurrently positioned on the circuit board with one carrier module 2.

The contacts 3 are not individually secured in the carrier module 2 compartments but only secured by the partitions 13 against tipping or falling out. The solder pins 9 of the contacts 3 extend downwardly through the carrier module through openings (not shown). In mounting the circuit board 5 the solder pins 9 pass through corresponding openings 8 of the circuit board and soldered to the circuit board to ensure electric bonding.

FIG. 3 shows a perspective exploded view of the circuit board arrangement 10 according to FIG. 1 with the lower portion of FIG. 3 showing the receiving module 6 which receives the circuit board 5.

In the illustration according to FIG. 3 the circuit board 5 has already been soldered to the electric connection modules 1, presently meaning that the contacts 3 are inserted into the corresponding openings 8 in the carrier modules 2 with their solder pins 9 where they are soldered.

To carry out the soldering process, contacts 3 are mounted on the carrier module 2, which may be done both manually and mechanically. The carrier module 2 is preferably mechanically brought to the circuit board 5 where it is positioned in a defined location relative to the circuit board 5. Then the circuit board 5 may be soldered to the contacts 3, which preferably occurs in a reflow process.

To this end for example the circuit board 5 with the carrier module 2 and the contacts arranged thereon is heated to a high temperature at which the soldering tin present in the openings 8 fuses on, soldering the circuit board 8 to the contacts 3. To supply the openings 8 with soldering tin the circuit board 8 has previously been knife-coated with soldering tin. Thus the openings 8 are provided with precisely defined, sufficient quantities of soldering tin. A soldering process may likewise be carried out with a soldering shaft.

To ensure a rapid soldering process and withstanding the temperatures occurring e.g. in a reflow process, the carrier modules 2 are made of a temperature-resistant plastic. The lightweight carrier module 2 substantially consisting of a skeleton frame has comparatively low heat capacity, allowing rapid soldering.

As the soldering process is finished, the primary function of the carrier module 2 has been fulfilled since subsequently to the soldering process the attachment module 4 is placed over the carrier module 2. The attachment module 4 subsequently achieves a contacting protection of each of the contacts 3 and comprises sufficient electric insulating properties to meet the required conditions, safety requirements, and legal provisions.

The attachment module 4 consists of a different, flexible plastic that withstands the loads and stresses occurring at the circuit board arrangement 10.

According to the invention a separation of functions is achieved in this way. The carrier module has the required thermal properties to maintain sufficient stability in high-temperature soldering processes while the attachment module 4 that may not be that temperature-resistant has the required mechanical and electric properties for contacting safety.

In the present exemplary embodiment the attachment module 4 is received at the receiving module 6 with latch openings 11 at the side walls of the attachment module 4 latching with latch lugs 12 of the receiving module 6, thus providing a reliable though detachable connection.

The invention also achieves that the electric connection modules 1 according to the invention can be soldered to the circuit board together with other components during one common soldering process since prior to the soldering process only contacts 3 are mounted to the carrier modules 2 and thereafter are soldered to the circuit board 5 in one common soldering process together with further components.

Consequently the invention allows a simplified, cost-effective manufacturing process since separate manual or automated soldering processes are dispensed with. Furthermore, material costs for the housings proper of the electric connection modules 1 can be saved since the attachment modules 4 do not need to be manufactured from the same high-temperature resistant material as are the carrier modules 2. For this purpose considerably less expensive types of plastic are sufficient, many of which have also considerably better electric and mechanical properties.

### LIST OF REFERENCE NUMERALS

1 electric connection module
2 carrier module
3 contact
4 attachment module
5 circuit board
6 receiving module
8 opening
9 solder pin
10 circuit board arrangement
11 latch opening
12 latch lug
13 partition
14 terminal opening
15 conductor

We claim:

1. An electric connection module (1) comprising:
a carrier module (2) composed of temperature-resistant plastic to be capable of withstanding a high-temperature soldering process;
at least one electric contact (3) in the carrier module;
an attachment module (4) composed of flexible plastic to protect the at least one electric contact (3);
a circuit board: and
the at least one electric contact soldered to the circuit board.

2. The electric connection module (1) according to claim 1 wherein an electric contact of an electric/electronic component is soldered to the circuit board.

3. The electric connection module (1) according to claim 1 wherein the attachment module (4) can be attached to the carrier module (2).

4. The electric connection module (1) according to claim 2 wherein the attachment module (4) serves as a mechanical connector.

5. The electric connection module (1) according to claim 2 wherein the temperature-resistant plastic of the carrier module (2) is suitable for soldering processes at temperatures of approximately 280° C., preferably for soldering processes at temperatures of approximately 240° C. to 260° C.

6. The electric connection module (1) according to claim 1 wherein the carrier module (2) consists of a liquid crystal polymer at least in part.

7. A circuit board arrangement (10) comprising:
a circuit board (5);
an electric connection module (1) with at least one carrier module (2);
at least one electric contact (3) that can be soldered to the circuit board (5) in a soldering process; and
at least one attachment module (4), wherein the carrier module (2) is provided to consist of a temperature-resistant plastic to be suitable for the high-temperature soldering process, and wherein the attachment module (4) is provided as a contacting protection of the at least one electric contact (3) and consists of a flexible plastic.

8. The circuit board arrangement (10) according to claim 7 wherein the attachment module (4) is attached to the carrier module (2) and to the circuit board (5).

9. The circuit board arrangement (10) according to claim 7 wherein the attachment module (4) is attached to a receiving module (6) that receives the circuit board (5) as well.

10. The circuit board arrangement (10) according to any claim 7 wherein at least one other electric/electronic component for soldering is provided on the circuit board (5) which can be soldered as well in the soldering process of the at least one electric contact (3).

11. The electric connection module (1) according to claim 2 wherein the attachment module (4) can be attached to the carrier module (2).

12. The electric connection module (1) according to claim 1 further comprising a receiving module designed of flexible plastic to accept the board and for fastening to the attachment module.

13. A method for creating an electric connection module comprising:
creating a carrier module of plastic which is capable of withstanding soldering process temperatures;
assembling at least one electric contact in the carrier module with pins from each contact extending below the carrier module;
selecting a board;
locating holes in the board to accept the pin from each contact;
coating the holes in the board with soldering tin;
positioning the carrier module such that the pin from each contact extends into a hole in the board; and
heating the carrier module and board to an appropriate temperature to allow the soldering tin to fuse each contact to the board.

14. A method for creating an electric connection module according to claim 13 further comprising:
selecting an attachment module created of flexible plastic to cover the carrier module and board;
securing the attachment module to the carrier module and board.

15. A method for creating an electric connection module according to claim 13 further comprising:
selecting an attachment module created of flexible plastic to cover the carrier module and board;
selecting a receiving module;
covering the carrier module and board with the attachment module; and
securing the attachment module to the receiving module.

16. The circuit board arrangement (10) according to claim 7 wherein the attachment module (4) is attached to the carrier module (2) or to the circuit board (5).
